(19) United States
(12) Patent Application Publication
(10) Pub. No.: US 2017/0317694 A1
(43) Pub. Date: Nov. 2, 2017

(54) ENCODING AND DECODING METHOD OF LOW-DENSITY PARITY-CHECK CODE

(71) Applicant: NATIONAL TSING HUA UNIVERSITY, HSINCHU (TW)

(72) Inventors: HUANG-CHANG LEE, Hsinchu City (TW); I-TSUN HUANG, Hsinchu City (TW); YEONG-LUH UENG, Hsinchu City (TW); CHIN-LIANG WANG, Hsinchu City (TW)

(73) Assignee: NATIONAL TSING HUA UNIVERSITY

(21) Appl. No.: 15/196,755

(22) Filed: Jun. 29, 2016

(30) Foreign Application Priority Data
Apr. 27, 2016 (TW) 105113145

(51) Int. Cl. H03M 13/11; H03M 13/00

(52) U.S. Cl. CPC H03M 13/1128; H03M 13/616

(57) ABSTRACT

An encoding and decoding method of low-density parity-check code is disclosed. The method is following steps: a high rate check code is transferred to a check matrix having a protograph. The check matrix is extended to form an extended base matrix and is split to form a split base matrix. The extended base matrix and the split base matrix are respectively calculated to generate their decoding threshold by a protograph extrinsic information transfer chart. The base matrix with the lower decoding threshold is considered as a low rate base matrix. Repeating the above process until a stop condition is satisfied. The last low rate base matrix is expanded to form a parity check matrix. The transmission data is encoded and decoded by the parity check matrix.

### CROSS-REFERENCE TO RELATED APPLICATION

This application claims the benefit of Taiwan Patent Application No. 105113145, filed on Apr. 27, 2016 in the Taiwan Intellectual Property Office, the disclosure of which is incorporated herein in its entirety by reference.

### BACKGROUND OF THE INVENTION

### 1. Field of the Invention

The present disclosure generally relates to an encoding and decoding method of low-density parity-check code, and in particular, to an encoding and decoding method of low-density parity-check code obtaining the rate compatible code by the manners of extension and splitting, as well as through a protograph.

### 2. Description of the Related Art

Under the current communication transfer mechanism, the data is encoded prior to being transferred and then is recovered to the source data by decoding. However, the interference, noise, and so on may lead to errors in the process of data transfer especially in the wireless transferring environment. For example, if the received data cannot be receiver to the source data bits after being decoded, the receiver will request the transmitter to transmit the data again. When re-transmitting the data, the transmitter will increase the check data bits to hereby protect the data bits from the failure in the recovery resulted from the interference. Hence, in respond to the retransmission, requirement and development of the rate compatible code are gradually raised. When establishing the rate compatible code, the added check code has to be compatible to the previous check code. So, manners of puncturing, extension and splitting, and so on are commonly used.

Nguyen et al. have disclosed a method encoding low-density parity-check code with a low rate compatible code in U.S. Pat. No. 8,689,083. The method is to use a protograph to establish the base matrix for the need of the maximum rate, and then the manners of puncturing and extension are applied to generate the replace matrix so as to obtain the desired parity check matrix. However, the high rate matrix is still embedded in the low rate matrix even though it uses the manners of puncturing and extension as disclosed in the prior art. Thus, the conventional technique for the low rate matrix is incapable of changing the connection between the variable nodes and the check nodes decided in the high rate matrix, resulting in the limitation to the usage. In addition, Jacobsen et al. have disclosed a method and system for encoding data using rate-compatible irregular LDPC codes based on edge growth and parity splitting in U.S. Pat. No. 7,966,548. The disclosure is to directly embody the extension and split in the parity check matrix and to use the Extrinsic Information Transfer Chart (EXIT chart) for deciding the ratio to the extension and the split. However, the complicated calculation is required, and the hardware apparatus with higher processing capability is also needed, so that the manners of encoding and decoding disclosed in the prior arts can be achieved successfully.

In conclusion, the known technique of establishing the compatibility of code rate indeed has the limitation and shortcomings. Hence, the inventor provides an encoding and decoding method of low-density parity-check code aiming to resolve the drawbacks so as to promote the industrial practicability.

### SUMMARY OF THE INVENTION

In view of the aforementioned technical problems, one objective of the present disclosure provides an encoding and decoding method of low-density parity-check code to resolve the technical problem of the complicated calculation of the compatibility of code rate and the operation thereof.

In accordance with one objective of the present disclosure, an encoding and decoding method of low-density parity-check code adapted to encoding or decoding data in a wireless communication network, the method is performed by a computing device and includes the following steps of: converting a high rate check code to a check matrix having a protograph; extending the check matrix to form an extended base matrix and splitting the check matrix to form a split base matrix; respectively calculating the extended base matrix and the split base matrix to generate a decoding threshold of the extended base matrix and the split base matrix by using a protograph extrinsic information transfer chart (P-EXIT chart), wherein one of the extended base matrix and the split base matrix with the lower decoding threshold is considered as a low rate base matrix; repeating the above steps until a stop condition is satisfied; expanding the low rate base matrix satisfied with the stop condition to form a parity check matrix; and encoding and decoding transmission data by the parity check matrix.

Preferably, the transmission data may be encoded by an encoder before being transmitted.

Preferably, after the transmission data is encoded and transmitted, the transmission data may be decoded by a decoder when the transmission data is received.

Preferably, a line may be split with a maximum weight in the check matrix.

Preferably, the expansion of the low rate base matrix may duplicate the protograph to enlarge variable nodes and check nodes of the low rate check matrix so as to form the complete parity check matrix.

Preferably, the same weights in the protograph may be replaced by one another.

Preferably, the stop condition may indicate that the decoding threshold reaches to a predetermined threshold value.

Preferably, the stop condition may indicate that the rate of low-density parity-check code reaches to a predetermined rate value.

As mentioned previously, the encoding and decoding method of low-density parity-check code in accordance with the present disclosure may have one or more advantages as follows.

The encoding and decoding method of low-density parity-check code is capable of demonstrating, the source code with high code rate to a simple base matrix through the design of the protograph, so as to reduce the complexity of the calculation and to promote the computational efficiency.

The encoding and decoding method of low-density parity-check code is capable of obtaining the complete parity check matrix through the expanding of the protograph when finding the optimal low rate base matrix. Besides, a shift register is used to simplify the complexity of hardware implementation.

The encoding and decoding method of low-density parity-check code is capable of splitting the high rate check nodes into multiple low rate check nodes through the combination of extension and split method, so that the connection among the variable nodes is modified to promote the flexibility of designing the check code.

### BRIEF DESCRIPTION OF THE DRAWINGS

FIG. 1 is a flow chart of the encoding and decoding method of low-density parity-check code in accordance with the present disclosure.

FIG. 2A and FIG. 2B are the schematic diagrams illustrating the relationship between the protograph base matrix and the parity check matrix in accordance with the present disclosure.

FIG. 3A and FIG. 3B are the schematic diagrams of the extended base matrix accordance with the present disclosure.

FIG. 4A and FIG. 4B are the schematic diagrams of the split base matrix in accordance with the present disclosure.

FIG. 5 is a schematic diagram of duplicating and selecting the low rate base matrix in accordance with the present disclosure.

FIG. 6 is a block diagram of the system of encoding and decoding a low-density parity-check in accordance with the present disclosure.

FIG. 7 is a block diagram of the communication system for transmitting data in accordance with the present disclosure.

FIG. 8 is a curve diagram illustrating the difference between the encoding and decoding method of low-density parity-check code in accordance with the present disclosure and the other methods.

FIG. 9 is a curve diagram illustrating the difference between the encoding and decoding method of low-density parity-check code in accordance with the present disclosure and the other wireless communication standards.

### DETAILED DESCRIPTION OF THE PREFERRED EMBODIMENTS

In the following description, specific details are presented to provide a thorough understanding of the embodiments at the present disclosure. Persons of ordinary skill in the art will recognize, however, that the present disclosure can be practiced without one or more of the specific details, or in combination with other components. Well-known implementations or operations are not shown or described in detail to avoid obscuring aspects of various embodiments of the present disclosure.

In accordance with the embodiment(s) of the present invention, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

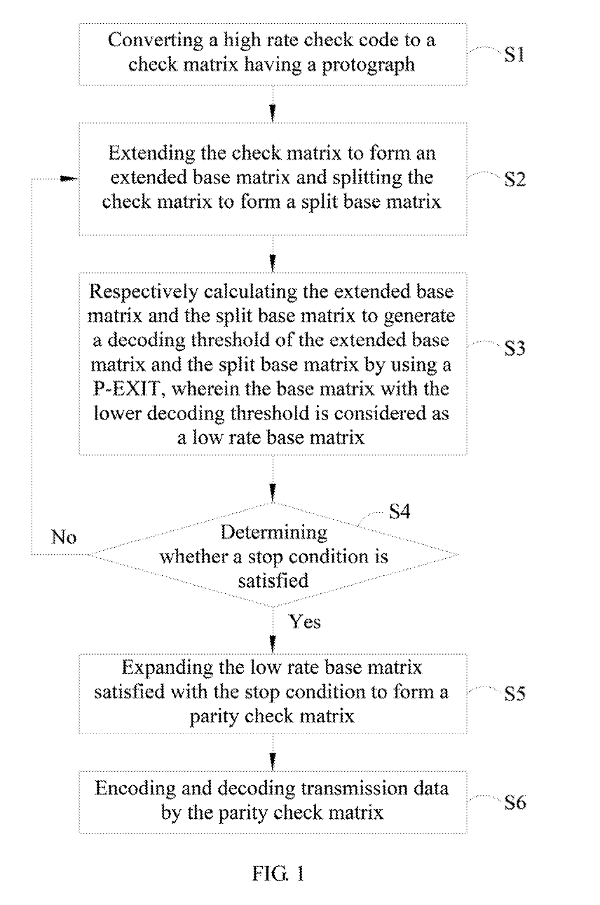

FIG. 1 is a flow chart of an encoding and decoding method of low-density parity-check code in accordance with the present disclosure. As shown in the figure, the method includes the following steps.

S1: Converting a high rate check code to a check matrix having a protograph. The protograph shows the initial code through a smaller Tanner graph derived from duplication and replacement. The protograph is applied to demonstrate the base matrix required for the high rate source code. The base matrix is used for the follow-up extension and split to form a low rate base matrix, so that the search number of codes in the process of establishing codes can be reduced. Besides, the effective encoding and decoding implemented in the physical hardware can be achieved, so as to reduce the complexity.

S2: Extending the check matrix to form an extended base matrix and splitting the check matrix to form a split base matrix. The source code with high rate is respectively extended and split to form a low rate check code, that is, the new lines (variable nodes) and the new rows (check nodes) are equivalently added to the protograph check matrix to form the extended base matrix to enable the original check matrix is embedded in the extended base matrix with low rate. At the same time, one row (check nodes) of the check matrix in the protograph is split into two rows, and one line (variable nodes) is added to indicate the connections between the two split rows, so as to form a split base matrix. Despite the act that the split check matrix does not completely keep the original check matrix, the new connections can maintain the split base matrix to be compatible to the original base matrix.

S3: Respectively calculating the extended base matrix and the split base matrix to generate the decoding threshold of the extended base matrix and the split base matrix by a protograph extrinsic information transfer chart (P-EXIT chart), and the base matrix with the lower decoding threshold is considered as the low rate base matrix. Basically, the Extrinsic Information Transfer Chart (EXIT chart) is to demonstrate the work through the extrinsic information exchange between the decoder for variable nodes and the decoder for the check nodes so as to show the dimension distribution between the variable nodes and the check nodes. The EXIT chart is used to predict the convergence property in the process of decoding and to analyze the characteristic of the low-density parity-check matrix. However, the general EXIT chart is incapable of considering the factor that the protograph having the same dimension has different decoding threshold, resulting in that the prediction cannot be made accurately. Therefore, the prediction of the practical connection between the variable nodes and the check nodes is shown through the protograph extrinsic information transfer chart. Besides, the decoding threshold of the extended base matrix and the split base matrix is calculated and then the decoding threshold values are compared, so that one of the extended base matrix and the spilt base matrix with the lower decoding threshold is considered as the low rate base matrix.

S4: Determining whether a stop condition is satisfied. When the low rate base matrix is found through the processes mentioned above, the low rate base matrix is used as the check matrix again, and the steps of extending and splitting are executed again to produce another extended check matrix and split check matrix. Then, the P-EXIT chart is applied to respectively calculate the decoding thresholds of the added extended check matrix and split check matrix so as to choose a further lower rate check code. The above process is repeated until the stop condition is satisfied. Here, the stopping condition includes that the decoding thresholds of the extended check matrix and the split check matrix reach to the predetermined threshold value, and alternatively, the rate reaches to the predetermined lowest rate value. After that, the chosen one of the extended check matrix and the split check matrix is served as the final result of the low rate base matrix. In addition, the condition can be set to stop when the extended or split has been executed by a certain times, and alternatively, to stop when the transmission data is received and checked to be accurate. The stop conditions are not limited to the above examples. The user may choose different stop conditions according to the required encoding and decoding settings.

S5: Expanding the low rate base matrix which is satisfied with the stop condition to form a parity check matrix. Since the steps mentioned above are all performed through the base matrix having the protograph, it has to extend the optimal low rate base matrix to form the parity check matrix that is practically encoding and decoding when the optimal low rate base matrix is found. The step of expanding is the same as described in step S1. By duplicating and replacing the protograph, the variable nodes and the check nodes of the low rate base matrix can be enlarged to form the complete parity check matrix. The same weights in the protograph can be replaced by one another when conducting the process of duplicating and replacing.

S6: Encoding and decoding the transmission data by the parity check matrix. When the optimal low rate parity check matrix is found, the data can be encoded. When the user receives the encoded data transmitted through wireless communication network, the data is decoded according to the same parity check matrix to confirm the correctness of the data. Regarding the method of encoding, it can refer to the papers such as Thomas J. Richardson and Rüdiger L. Urbanke, “Efficient Encoding of Low-Density Parity-Check Codes,” IEEE TRANSACTIONS ON INFORMATION THEORY, VOL. 47, NO. 2, FEBRUARY 2001 and Z. W. Li et al, “Efficient encoding of qusa-cyclic low-density parity-check codes,” IEEE Trans. Commun., vol. 54, no. 1, pp. 71-78, January 2006. Besides, as to the method of decoding, it can refer to the decoding algorithms such as Sum-Product Algorithm (SPA) provided by T. J. Richardson and R. Urbanke, “The capacity of low-density paritycheck codes under message-passing decoding,” IEEE Trans. Inform. Theory, vol. 47, pp. 599-618, February 2001, and the Min-Sum Algorithm provided by J. Chen and M. Fossorier. New optimum universal belief propagation based decoding of LDPC codes. IEEE Trans. on Comm., 50 (3), March 2002.

The following paragraphs will detail the process of the encoding and decoding method of low-density parity-check code with practical embodiment.

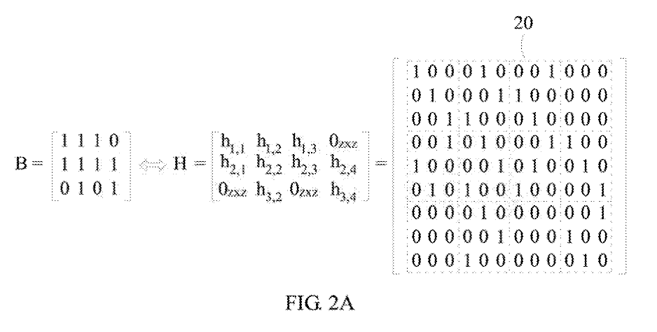

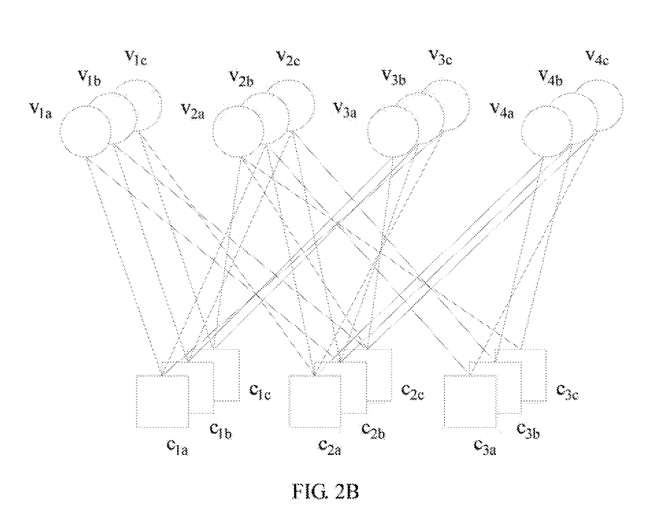

Please refer to FIG. 2A and FIG. 2B which are the schematic diagrams illustrating the relationship between the protograph base matrix and the parity check matrix in accordance with the present disclosure. As shown in FIG. 2B, the parity check matrix H demonstrated in the Tanner graph displays the connection relationship to 9 check nodes (C1ₐ, C1_{b}, . . . , C3_{c}) and 12 variable nodes (V1ₐ, V1_{b}, . . . V4_{c}). Such connection relationship is displayed by the original matrix 20 formed of 9 rows with 12 lines as shown in FIG. 2A. The original matrix 20 is divided into a plurality of protographs: (h_{1,1}, h_{1,2}, . . . h_{3,4}) and zero matrix 0_{zxz}. Wherein, the weights of the row and the lines in the protographs (h_{1,1}, h_{1,2}, . . . h_{3,4}) are the same, and the same weights in the protograph can be replaced by one another, so that various protographs can be formed by such manner. The codes displayed in the original matrix 20 are transformed into the base matrix B having the protograph, and the base matrix is used for the follow-up extension and split. As using the base matrix B to perform the calculation can reduce the amount for searching the better codes in the process of extending and splitting, so that the complex calculation can be simplified greatly. Besides, since the lines and rows of the matrix can be converted to form the protograph with the same weights, the hardware implementation can be simplified by using a swift register, so as to promote the computational efficiency and to simplify the hardware apparatus. Similarly, when the optimal low rate base matrix is selected, the protograph can be applied to duplicate the optimal low rate base matrix for replacing the codes in the low rate base matrix, so that the variable nodes and the check nodes are enlarged by bringing into the protograph. As a result, the complete parity check matrix, and the parity check matrix is used to encode or decode the transmission data.

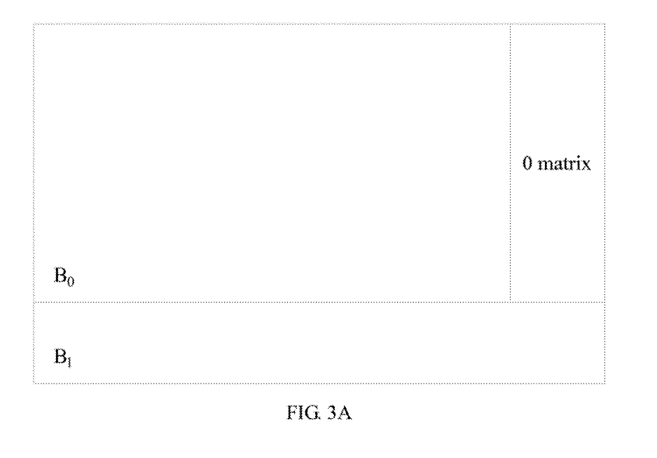

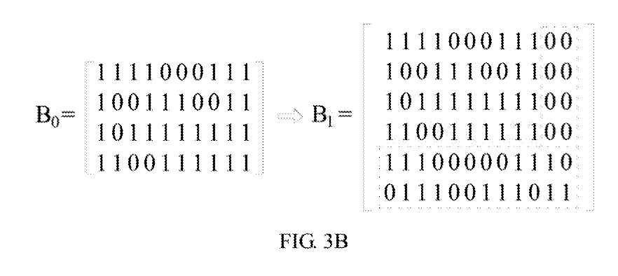

Please refer to FIG. 3A and FIG. 3B which are the schematic diagrams of the extended base matrix in accordance with the present disclosure. As shown in FIG. 3A, the high rate base matrix B₀ forms the extended low rate base matrix B₁ by equivalently adding lines (variable nodes) and rows (check nodes) of the matrix; wherein the added variable nodes are only connected to the added check nodes correspondingly. That is, the portion of the variable modes of the base matrix B₀ which is not connected to the added check nodes is filled by zero matrix. The numbers of rows and lines of the base matrix B₀ are denoted as M₀ and N₀ respectively, and the formation of the rows and lines are by P₀(X) and Q₀(X) denoted respectively. The relationship shows as follows.

P₀(X)=a_{N}_{₀}X^{N}^{₀}+a_{N}_{ₒ}₋₁X^{N}^{₀}⁻¹+ . . . +a₂X (1)

Q₀(X)=b_{M}_{₀}X^{M}^{₀}+b_{M}_{₀}₋₁X^{M}^{₀}⁻¹+ . . . +b₂X (2)

Here, aᵢXⁱ means that the base matrix B₀ with aᵢ rows is Xⁱ in the weights (the number of 1), i∈{N₀ . . . 0}, and Σᵢ₌₁^{N}^{₀} aᵢ=N₀. In addition, Σⱼ₌₁^{M}^{₀} bⱼ=M₀, j∈{M₀ . . . 0}.

If the extended base matrix B₁ is extended to be one row with one line, the row of the extended base matrix B₁ is denoted as P₁(X). The relationship is P₁(X)=P₀(X)+X^{e}^{₁}, e₁∈{0 . . . N₀+1} (3). Thus, it can be seen that if the extension is applied, rows with nigh rate are included in that with low rate, that is, the high rate base matrix B₀ has been embedded in the extended low rate base matrix B₁. Hence, the rates respectively shown in the base matrix B₀ and the base matrix B₁ are compatible.

In practice, as shown in FIG. 3B, N₀=10 and M₀=4 in the base matrix B₀.Here, the row and line are respectively denoted as P₀(X)=X⁹+X⁸+X⁷+X⁶, Q₀(X)=3X⁴+4X³+3X². If the base matrix B₀ is extended, two rows are added to extend the base matrix B₀ to obtain the extended base matrix B₁. The relationship is P₁(X)=P₀(X)+(X⁸+X⁶). Here, the added variable nodes are only connected to the added check nodes in the two added extended lines, so the lines added corresponding to the base matrix B₀ is denoted by zero matrix.

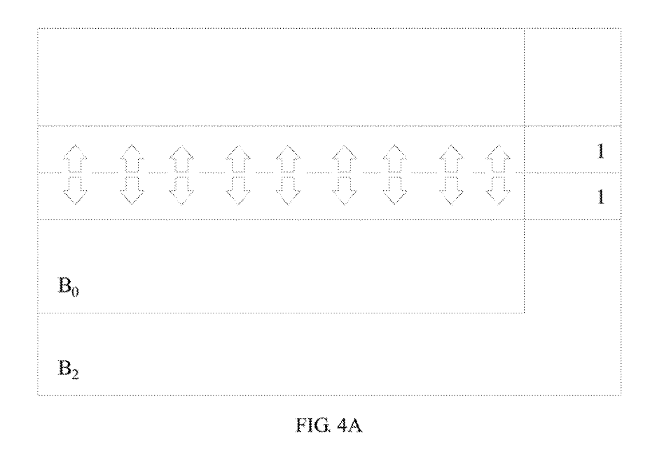

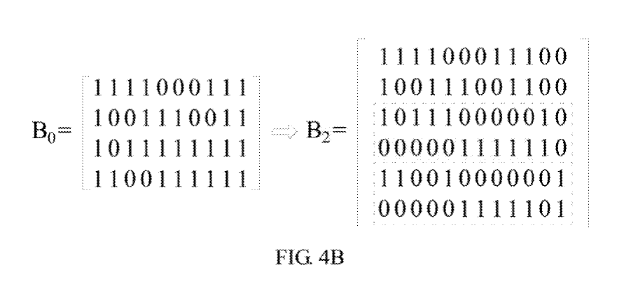

Please refer to FIG. 4A and FIG. 4B which are the schematic diagrams of the split base matrix in accordance with the present disclosure. As shown in FIG. 4A, the check nodes of the high rate base matrix B₀ is divided into 2, and the split check nodes are connected with each other to maintain the information exchange between the original check nodes and the variable nodes to form the split low rate base matrix B₂. In the process of splitting, the cycle girth is continuously being enlarged to prevent the occurrence of lower cycle girth in the low-density parity check code matrix. Therefore, based on the same representation of the base matrix B₀, if the base matrix B₂ is formed by splitting method, one row of the base matrix B₀ is split into two rows while a line with a weight of 2 is added thereto. And the two numbers of 1 on the line are respectively on the two split rows. Therefore, the split base matrix B₂ is as follows: P₂(X)=P₀(X)−X^{s}^{₁}+X^{v}^{₁}⁺¹+X^{w}^{₁}⁺¹, s₁∈{0 . . . N₀}, v₁+w₁=s₁ (4). In addition, the lines denoted as Q₂(X)=Q₀(X)+X². The split base matrix B₂ and the base matrix B₀ are compatible in terms of the rates thereof.

In practice as shown in FIG. 4B, the method is the same as the former embodiment displaying the initializing the base matrix B₀, and N₀=10, M₀=4. So, if the third row and the fourth row of the base matrix B₀ are split into two rows, it can obtain the split base matrix B₂, and the relationships thereof are respectively denoted as P₁(X)=P₀(X)+(−X⁹+X⁽⁵⁺¹⁾+X⁽⁴⁺¹⁾+(−X⁸+X⁽³⁺¹⁾+X⁽⁵⁺¹⁾) and Q₁(X)=Q₁(X)+2X². In the two added lines, the split variable nodes are applied to connect to the added check nodes to maintain the compatibility, and the added lines without being split is denoted as zero matrix. For the sake of avoiding added extended variable nodes and the check nodes causing the cycle-4 loop in the check matrix when performing the splitting, the row with the maximum weight is selected to be split so as to prevent the presence of the check matrix with short cycle to effect the effect of the encoding and decoding.

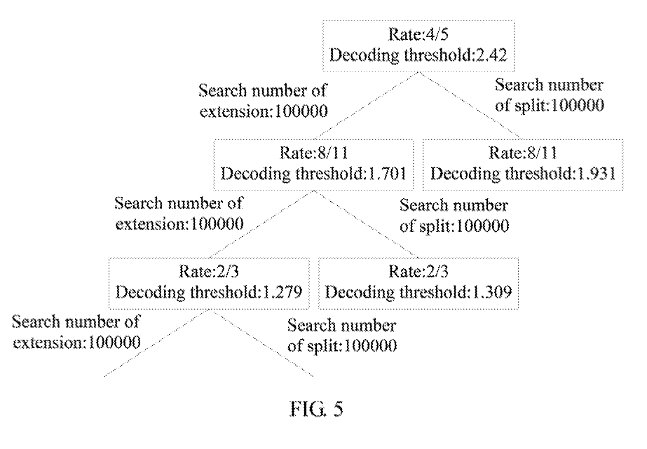

Please refer to FIG. 5 which is a schematic diagram of duplicating and selecting the low rate base matrix in accordance with the present disclosure. As the steps disclosed in the preceding embodiments, after the protograph base matrix is respectively extended and split to obtain the lower rate extended base matrix and the split base matrix, the P-EXIT chart is applied to calculate the decoding threshold thereof. And the obtained decoding threshold is set as the standard of selecting the optimal base matrix. As shown in the figure, the rate of the original code is ⅘, and the decoding threshold is 2.42, that is, the original code is the check code with the maximum rate. After extending and splitting, the sub-codes of 8/11 are generated, and the decoding thresholds of the extended base matrix and the split base matrix are respectively 1.701 and 1.931. So, the extended base matrix is selected as the lower rate base matrix. Next, the selected extended base matrix is served as the check matrix in step S2 to be extended and, split again, so that it can further form the extended base matrix and the split base matrix with lower rate (rate is ⅔). After that, the decoding threshold is calculated to be served as the index of the judgment. The steps mentioned above are repeated until the stop condition is satisfied. Here, the stop condition means that the predetermined decoding threshold value is satisfied or the predetermined lowest rate is met. Consequently, the last chosen base matrix is the optimal low rate base matrix.

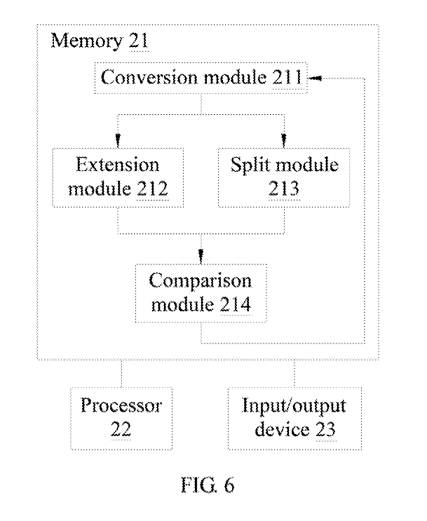

Please refer to FIG. 6 which is a block diagram of the system of encoding and decoding a low-density parity-check in accordance with the present disclosure. As shown in the figure, a conversion module 211 is used to convert the high rate source check code into the check matrix having the protograph. The extension module 212 extends the check matrix to be the extended base matrix, and the splitting module 213 splits the check matrix into the split base matrix so as to calculate the decoding thresholds of the extended base matrix and the split base matrix. In addition, a comparison module 214 is used to select the base matrix with lower rate as the low rate base matrix. When the low rate base matrix that satisfies the stop condition is found, the conversion module 211 is used to expand the base matrix to form the parity check matrix. The modules mentioned above are designed as a manner of software program and stored in a non-transitory computer readable medium, such as a memory 21. A processor 22 is configured to access the memory 21 and to execute the above computing modules. In addition, the transmission data to be encoded or decoded can be input by an input/output device 23 and output after being encoded. The memory 21 hides read-only memory, flash memory device, disk, and so on. The processor includes central processing unit, microprocessor, and so on. The input/output device 23 includes various input interfaces such as keyboards, mice, touch devices, and output interfaces for display, transmitter, and so on.

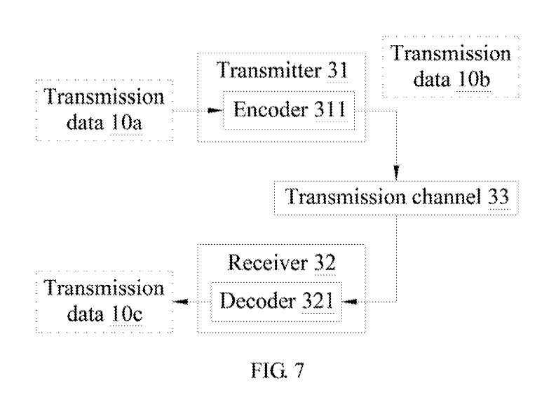

Please refer to FIG. 7 which is a block diagram of the communication system for transmitting data in accordance with the present disclosure. As shown in the figure, the transmission data 10a is transmitted to a transmitter 31. The transmitter 31 mentioned herein may be a computing device such as a personal computer, smart phone, server, and so on, and the transmitter may include an encoder 311 of a system for encoding and decoding the low-density parity-check code as described in FIG. 6. The encoder 311 encodes the transmission data 10a as through the low-density parity-check code, and then the transmission data 10a transmitted to a receiver 32 through a transmission channel 33. The receiver 32 mentioned herein may be the same or different receiving device to the transmitter 31. The transmission channel 33 may include various wireless transmission technologies such as wireless network transmission, wireless communication transmission, and so on, but it shall not be limited thereto. The manner of transmitting data by cable network is so included in the present disclosure. The encoded transmission data 10b is transmitted from the transmitter 31 to the receiver 32. When the receiver 32 receives the data, a decoder 321 disposed in the receiver 32 is applied to decode the encoded data through the low-density parity-check code to confirm whether the data is successfully received. If errors occur, the transmitter 31 is asked to encode data with the lower rate check code and then transmits the encoded data again. The transmitting is repeated until the transmission data 10b is successfully received by the receiver 32 and the original transmission data 10c is recovered.

After being extended and split, the low-density parity-check code applied in the present disclosure firstly selects the better base matrix, and then the process is repeated until the optimal low rate base matrix is found. In the steps, the original base matrix may be extended and split to produce lower rate base matrix. In other words, compared with obtaining the check code through either extension or split, the present disclosure, which applies both extension and split, can obtain a better check code. It is therefore achieving better technical effect of encoding and decoding than the conventional technique. In addition, compared with the extension and puncturing, the manner of applying both extension and split indeed overcomes the drawbacks that the connection state between the variable nodes and check nodes in the high rate base matrix can be changed. Besides, the application of protograph not only can promote the computational efficiency, but also simplify the hardware implements of encoding and decoding. As a consequence, the encoding and decoding method of low-density parity-check code provided in the present disclosure absolutely achieves the technical effect that the conventional technique fails to achieve. The comparison is stated as follows.

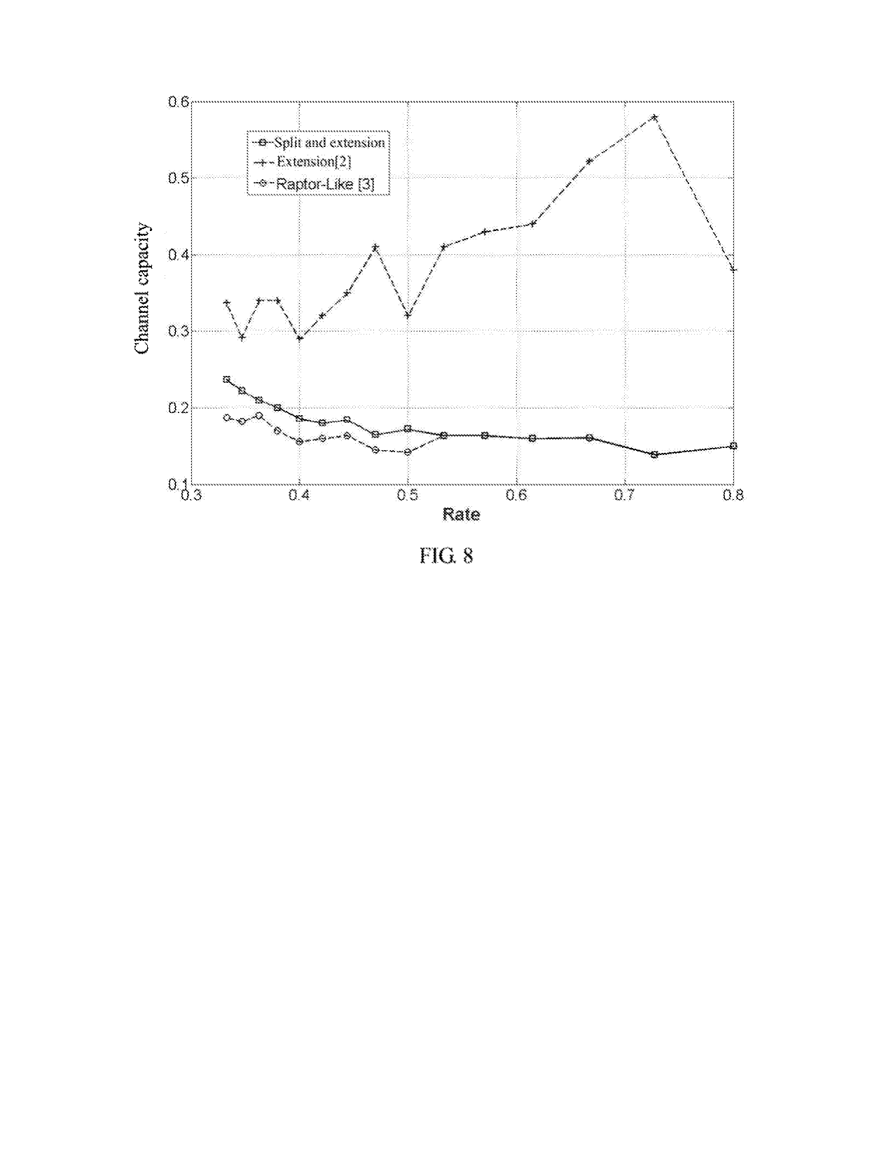

Please refer to FIG. 8 which is a curve diagram illustrating the difference between the encoding and decoding method of low-density parity-check code in accordance with the present disclosure and the other methods. As shown in the figure, compared with the Raptor-like Codes, the method of extending and splitting provided in the present disclosure is closer to the Gap to capacity. In addition, with the increase of codes, the method of extending and splitting provided in the present disclosure demonstrates the better rate than the check code with only the manner of extending.

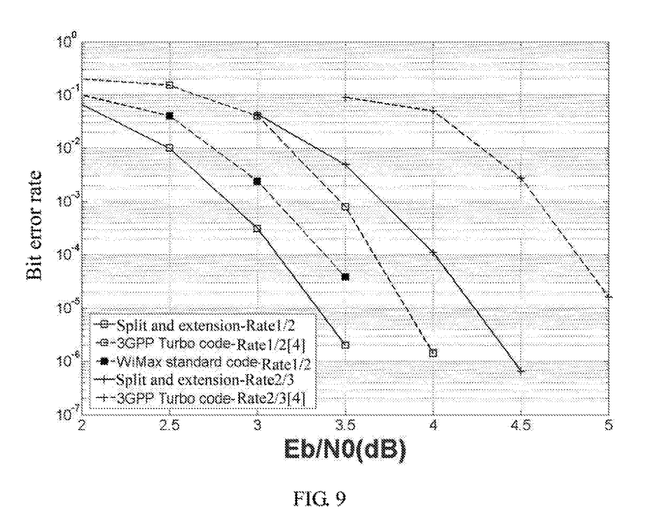

Please refer to FIG. 9 which is a curve diagram illustrating the difference between the encoding and decoding method of low-density parity-check code in accordance with the present disclosure and the other wireless communication standards. As shown in the figure, the code with ½ rate and ⅓ rate selected by the present disclosure is used to compare with the code applied to the wireless communication standards such as 3G, WiMax, and so on. According to the simulation result of the Bit Error Rate (BER) it can be found that the method of extending and splitting provided in the present disclosure demonstrates better control over the current standards.

While the means of specific embodiments in present disclosure has been described by reference drawings, numerous modifications and variations could be made thereto by those skilled in the art without departing from the scope and spirit of the disclosure set forth in the claims. The modifications and variations should in a range limited by the specification of the present disclosure.

What is claimed is:

1. An encoding and decoding method of low-density parity-check code adapted to encoding or decoding data in a wireless communication network, the method being performed by a computing device and comprising following steps of:
converting a high rate check code to a check matrix having a protograph;
extending the check matrix to form an extended base matrix and splitting the check matrix to form a split base matrix;
respectively calculating the extended base matrix and the split base matrix to generate a decoding threshold of the extended base matrix and the split base matrix by using a protograph extrinsic information transfer chart, wherein one of the extended base matrix and the split base matrix with the lower decoding threshold is considered as a low rate base matrix;
repeating the above steps until a stop condition is satisfied;
the low rate base matrix satisfied with the stop condition to form a parity check matrix; and
encoding and decoding transmission data by the parity check matrix.

2. The encoding and decoding method of low-density parity-check code of claim 1, wherein the transmission data is encoded by an encoder before being transmitted.

3. The encoding and decoding method of low-density parity-check code of claim 2, wherein after the transmission data is encoded and transmitted, the transmission data is decoded by a decoder when the transmission data is received.

4. The encoding and decoding method of low-density parity-check code of claim 1, wherein a line is split with a maximum weight in the check matrix.

5. The encoding and decoding method of low-density parity-check code of claim 1, wherein the expansion of the low rate base matrix is to duplicate the protograph to enlarge variable nodes and check nodes of the low rate check matrix so as to form complete parity check matrix.

6. The encoding and decoding method of low-density parity-check code of claim 5, wherein the same weights in the protograph are replaced by one another.

7. The encoding and decoding method of low-density parity-check code of claim 1, wherein the stop condition indicates that the decoding threshold reaches to a predetermined threshold value.

8. The encoding and decoding method of low-density parity-check code of claim 1, wherein the stop condition indicates that the rate of low-density parity-check code reaches to a predetermined rate value.
